(19) United States
(12) Patent Application Publication
(10) Pub. No.: US 2012/0306026 A1
(43) Pub. Date: Dec. 6, 2012

(54) REPLACEMENT GATE ELECTRODE WITH A TUNGSTEN DIFFUSION BARRIER LAYER

(75) Inventors: Dechao Guo, Fishkill, NY (US); Shu-Jen Han, Cortlandt Manor, NY (US); Keith Kwong Hon Wong, Wappingers Falls, NY (US); Jun Yuan, Fishkill, NY (US)

(73) Assignee: INTERNATIONAL BUSINESS MACHINES CORPORATION, Armonk, NY (US)

(21) Appl. No.: 13/118,750

(22) Filed: May 31, 2011

(51) Int. Cl. H01L 29/78; H01L 21/336

(52) U.S. Cl. 257/407; 438/299; 257/E29.255; 257/E21.409

(57) ABSTRACT

A tungsten barrier portion is employed in a replacement gate structure to block diffusion of material from a metal portion to a work function material portion. The tungsten barrier portion effectively functions as a diffusion barrier layer between the metal portion and the work function material portion so that the composition of the work function material portion is unaffected by anneal and/or usage of the field effect transistor including the replacement gate structure. Thus, the threshold voltage of the field effect transistor can remain stable throughout processing steps and usage in the field.

### BACKGROUND

The present disclosure generally relates to semiconductor devices, and particularly to semiconductor structures having dual work function material gates and a high-k gate dielectric, and methods of manufacturing the same.

In general, dual metal gate complementary metal oxide semiconductor (CMOS) integration schemes employ two gate materials, one having a work function near the valence band edge of the semiconductor material in the channel and the other having a work function near the conduction band edge of the same semiconductor material. In CMOS devices having a silicon channel, a conductive material having a work function of 4.0 eV is necessary for p-type metal oxide semiconductor field effect transistors (NMOSFETs, or “NFETs”) and another conductive material having a work function of 5.1 eV is necessary for n-type metal oxide semiconductor field effect transistors (PMOSFETs, or “PFETs”). In conventional CMOS devices employing polysilicon gate materials, a heavily p-doped polysilicon gate and a heavily n-doped polysilicon gate are employed to address the needs. In CMOS devices employing high-k gate dielectric materials, two types of gate stacks comprising suitable materials satisfying the work function requirements are needed for the PFETs and for the NFETS, in which the gate stack for the PFETs provides a flat band voltage closer to the valence band edge of the material of the channel of the PFETs, and the gate stack for the NFETs provides a flat band voltage closer to the conduction band edge of the material of the channel of the NFETs. In other words, threshold voltages need to be optimized differently between the PFETs and the NFETs.

Two types of gate electrodes are employed in dual metal gate CMOS integration schemes to provide a first work function at or near the valence band edge and a second work function at or near the conduction band edge of the underlying semiconductor material such as silicon. Typically, two types of gate cavities are provided and filled with a same dielectric material to form gate dielectrics. The two types of gate cavities are filled with different types of conductive materials to form gate stacks having different work functions. For example, a first work function material layer contacting a first gate dielectric is employed in a first type gate stack to provide the first work function, and a second work function material layer contacting a second gate dielectric is employed in a second type gate stack to provide the second work function. A conductive material layer fills remaining portions of the gate cavities. The conductive material layer typically includes aluminum, which flows easily to completely fill the gate cavities. Aluminum has a band gap close to the conduction band edge of silicon. Thus, diffusion of aluminum to a p-type band gap edge material layer that can affect the work function of a p-type field effect transistor that employs a gate employing the p-type band gap edge material layer, and introduce unpredictable shift in threshold voltages in the p-type field effect transistor depending on the amount and degree of diffusion of aluminum into the p-type band gap edge material layer.

### BRIEF SUMMARY

A tungsten barrier portion is employed in a replacement gate structure to block diffusion of material from a metal layer to a work function material portion. The tungsten barrier portion effectively functions as a diffusion barrier layer between the metal portion and the work function material portion so that the composition of the work function material portion is unaffected by anneal and/or usage of the field effect transistor including the replacement gate structure. Thus, the threshold voltage of the field effect transistor can remain stable throughout processing steps and usage in the field.

According to an aspect of the present disclosure, a semiconductor structure including a field effect transistor is provided. The field effect transistor includes a gate dielectric located on a semiconductor substrate; at least one work function material portion contacting the gate dielectric; a tungsten barrier portion contacting the at least one work function material portion; and a metal portion contacting the tungsten barrier portion.

According to another aspect of the present disclosure, a method of forming a semiconductor structure including a field effect transistor (FET) is provided. The method includes: forming a planarization dielectric layer on a semiconductor substrate; forming a gate cavity, wherein the planarization dielectric layer laterally surrounds the gate cavity and a top surface of the semiconductor substrate is exposed at a bottom of the gate cavity; forming a gate dielectric within the gate cavity; forming at least one work function material portion on the gate dielectric; forming a tungsten barrier portion on at least one work function material portion; and forming a metal portion on the tungsten barrier portion, wherein the gate dielectric, the at least one work function material portion, the tungsten barrier portion, and the metal portion fill the gate cavity.

### BRIEF DESCRIPTION OF THE SEVERAL VIEWS OF THE DRAWINGS

FIG. 1 is vertical cross-sectional view of an exemplary semiconductor structure after formation of disposable gate level layers according to an embodiment of the present disclosure.

FIG. 2 is a vertical cross-sectional view of the exemplary semiconductor structure after patterning of disposable gate structures and formation of source/drain extension regions according to an embodiment of the present disclosure.

FIG. 3 is a vertical cross-sectional view of the exemplary semiconductor structure after formation of source/drain trenches according to an embodiment of the present disclosure.

FIG. 4 is a vertical cross-sectional view of the exemplary semiconductor structure after formation of embedded stress-generating source/drain regions according to an embodiment of the present disclosure.

FIG. 5 is a vertical cross-sectional view of the exemplary semiconductor structure after deposition and planarization of a planarization dielectric layer according to an embodiment of the present disclosure.

FIG. 6 is a vertical cross-sectional view of the exemplary semiconductor structure after removal of the disposable gate structures according to an embodiment of the present disclosure.

FIG. 7 is a vertical cross-sectional view of the exemplary semiconductor structure after formation of a gate dielectric layer and a first work function material layer according to an embodiment of the present disclosure.

FIG. 8 is a vertical cross-sectional view of the exemplary semiconductor structure after removal of exposed portions of the first work function material layer from a second field effect transistor region according to an embodiment of the present disclosure.

FIG. 9 is a vertical cross-sectional view of the exemplary semiconductor structure after formation of a second work function material layer according to an embodiment of the present disclosure.

FIG. 10 is a vertical cross-sectional view of the exemplary semiconductor structure after deposition of a tungsten barrier layer according to an embodiment of the present disclosure.

FIG. 11 is a vertical cross-sectional view of the exemplary semiconductor structure after deposition of a metal layer according to an embodiment of the present disclosure.

FIG. 12 is a vertical cross-sectional view of the exemplary semiconductor structure after planarization according to an embodiment of the present disclosure.

FIG. 13 is a vertical cross-sectional view of the exemplary semiconductor structure after formation of a contact level dielectric layer and contact via structures according to an embodiment of the present disclosure.

### DETAILED DESCRIPTION

As stated above, the present disclosure relates to semiconductor devices, and particularly to semiconductor structures having dual work function material gates and a high-k gate dielectric, and methods of manufacturing the same, which are now described in detail with accompanying figures. Like and corresponding elements mentioned herein and illustrated in the drawings are referred to by like reference numerals. The drawings are not necessarily drawn to scale.

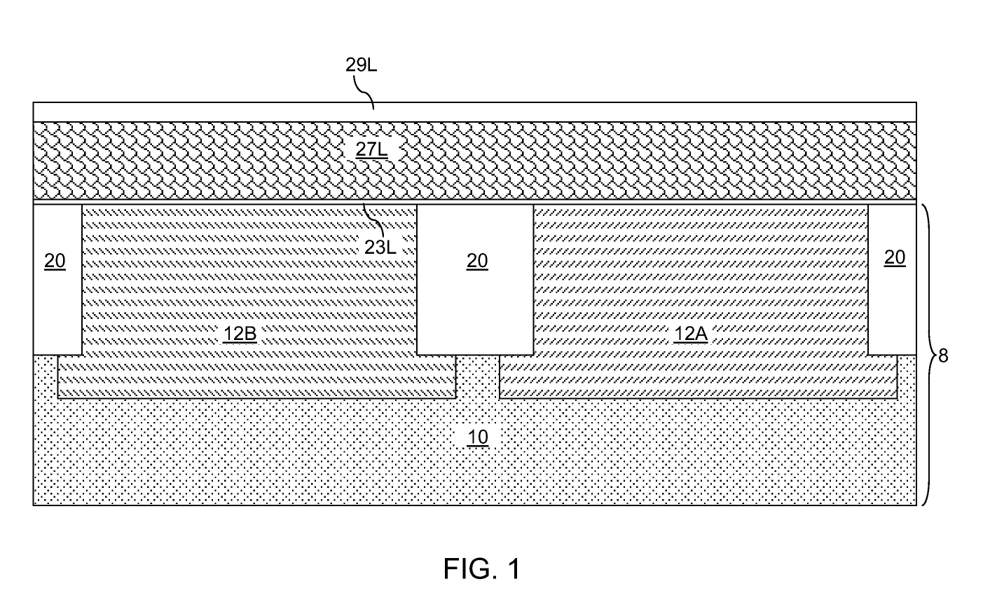

Referring to FIG. 1, an exemplary semiconductor structure according to an embodiment of the present disclosure includes a semiconductor substrate 8, on which various components of field effect transistors are subsequently formed. The semiconductor substrate 8 can be a bulk substrate including a bulk semiconductor material throughout, or a semiconductor-on-insulator (SOI) substrate (not shown) containing a top semiconductor layer, a buried insulator layer located under the top semiconductor layer, and a bottom semiconductor layer located under the buried insulator layer.

Various portions of the semiconductor material in the semiconductor substrate 8 can be doped with electrical dopants of n-type or p-type at different dopant concentration levels. For example, the semiconductor substrate 8 may include an underlying semiconductor layer 10, a second conductivity type well 12A formed in a first device region (the region on the left side in FIG. 1), and a first conductivity type well 12B formed in a second device region (the region on the right side in FIG. 1). The first conductivity type well 12B is doped with dopants of a first conductivity type, which can be n-type or p-type. The second conductivity type well 12A is doped with dopants of a second conductivity type, which is the opposite of the first conductivity type. If the first conductivity type is p-type, the second conductivity type is n-type, and vice versa.

Shallow trench isolation structures 20 are formed to laterally separate each of the first conductivity type well 12B and the second conductivity type well 12A. Typically, each of the first conductivity type well 12B and the second conductivity type well 12A is laterally surrounded by a contiguous portion of the shallow trench isolation structures 20. If the semiconductor substrate 8 is a semiconductor-on-insulator substrate, bottom surfaces of the first conductivity type well 12B and the second conductivity type well 12A may contact a buried insulator layer (not shown), which electrically isolates each of the first conductivity type well 12B and the second conductivity type well 12A from other semiconductor portions of the semiconductor substrate 8 in conjunction with the shallow trench isolation structures 20. In one embodiment, topmost surfaces of the shallow trench isolation structures can be substantially coplanar with topmost surfaces of the first conductivity type well 12B and the second conductivity type well 12A.

Disposable gate level layers are deposited on the semiconductor substrate 8 as blanket layers, i.e., as unpatterned contiguous layers. The disposable gate level layers can include, for example, a vertical stack a disposable gate dielectric layer 23L, a disposable gate material layer 27L, and a disposable gate cap dielectric layer 29L. The disposable gate dielectric layer 23L can be, for example, a layer of silicon oxide, silicon nitride, or silicon oxynitride. The thickness of the disposable gate dielectric layer 23L can be from 1 nm to 10 nm, although lesser and greater thicknesses can also be employed. The disposable gate material layer 27L includes a material that can be subsequently removed selective to the dielectric material of a planarization dielectric layer to be subsequently formed. For example, the disposable gate material layer 27L can include a semiconductor material such as a polycrystalline semiconductor material or an amorphous semiconductor material. The thickness of the disposable gate material layer 27L can be from 30 nm to 300 nm, although lesser and greater thicknesses can also be employed. The disposable gate cap dielectric layer 29L can include a dielectric material such as silicon oxide, silicon nitride, or silicon oxynitride. The thickness of the disposable gate cap dielectric layer 29L can be from 3 nm to 30 nm, although lesser and greater thicknesses can also be employed. While the present disclosure is illustrated with disposable gate level layers including a vertical stack a disposable gate dielectric layer 23L, a disposable gate material layer 27L, and a disposable gate cap dielectric layer 29L, any other disposable gate level layers can also be employed provided that the material(s) in the disposable gate level layers can be removed selective to a planarization dielectric layer to be subsequently formed.

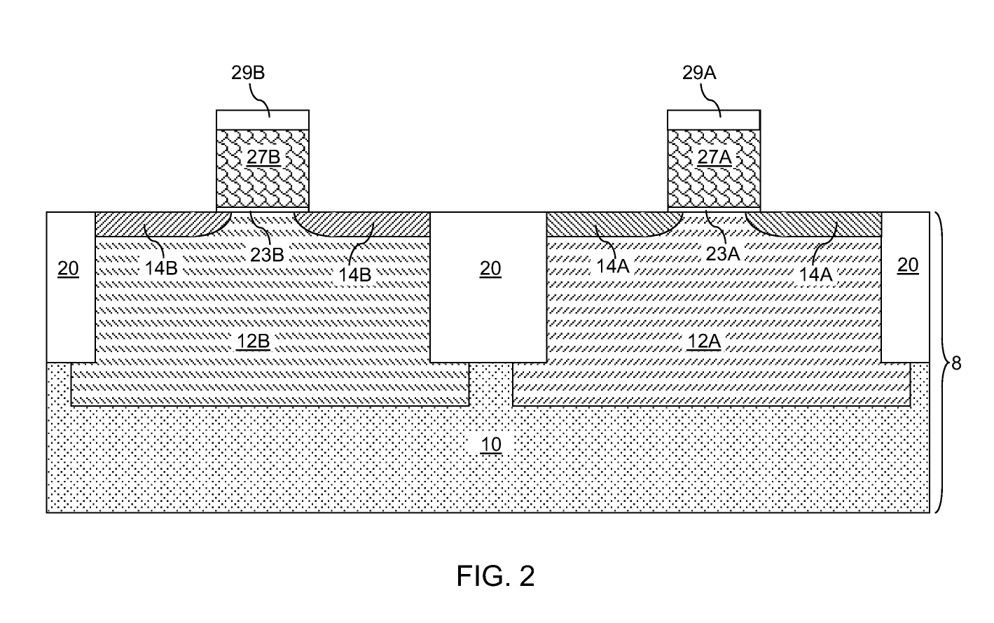

Referring to FIG. 2, the disposable gate level layers (29L, 27L, 23L) are lithographically patterned to form disposable gate structures. Specifically, a photoresist (not shown) is applied over the topmost surface of the disposable gate level layers (29L, 27L, 23L) and is lithographically patterned by lithographic exposure and development. The pattern in the photoresist is transferred into the disposable gate level layers (29L, 27L, 23L) by an etch, which can be an anisotropic etch such as a reactive ion etch. The remaining portions of the disposable gate level layers (29L, 27L, 23L) after the pattern transfer constitute disposable gate structures.

The disposable gate stacks may include, for example, a first disposable gate structure formed over the second conductivity type well 12A in the first device region and a second disposable gate structure formed over the first conductivity type well 12B in the second device region. The first disposable gate structure is a stack of a first disposable gate dielectric portion 23A, a first disposable gate material portion 27A, and a first disposable gate cap portion 29A, and the second disposable gate structure is a stack of a second disposable gate dielectric portion 23B, a second disposable gate material portion 27B, and a second disposable gate cap portion 29B. The first disposable gate cap portion 29A and the second disposable gate cap portion 29B are remaining portions of the disposable gate cap dielectric layer 29L. The first disposable gate material portion 27A and the second disposable gate material portion 27B are remaining portions of the disposable gate material layer 27L. The first disposable gate dielectric portion 23A and the second disposable gate dielectric portion 23B are remaining portions of the disposable gate dielectric layer 23L.

Masked ion implantations can be employed to form various source/drain extension regions. For example, dopants of the first conductivity type can be implanted into portions of the second conductivity type well 12A that are not covered by the first disposable gate structure (23A, 27A, 29A) to form first source/drain extension regions 14A having a doping of the first conductivity type. The first conductivity type well 12B can be masked by a patterned photoresist (not shown) during this implantation process to prevent implantation of additional dopants of the first conductivity type therein. As used herein, “source/drain extension regions” collectively refer to source extension regions and drain extension regions. Similarly, dopants of the second conductivity type can be implanted into portions of the first conductivity type well 12B that are not covered by the second disposable gate structure (23B, 27B, 29B) to form second source/drain extension regions 14B. The second conductivity type well 12A can be masked by another patterned photoresist (not shown) during this implantation process to prevent implantation of dopants of the second conductivity type therein.

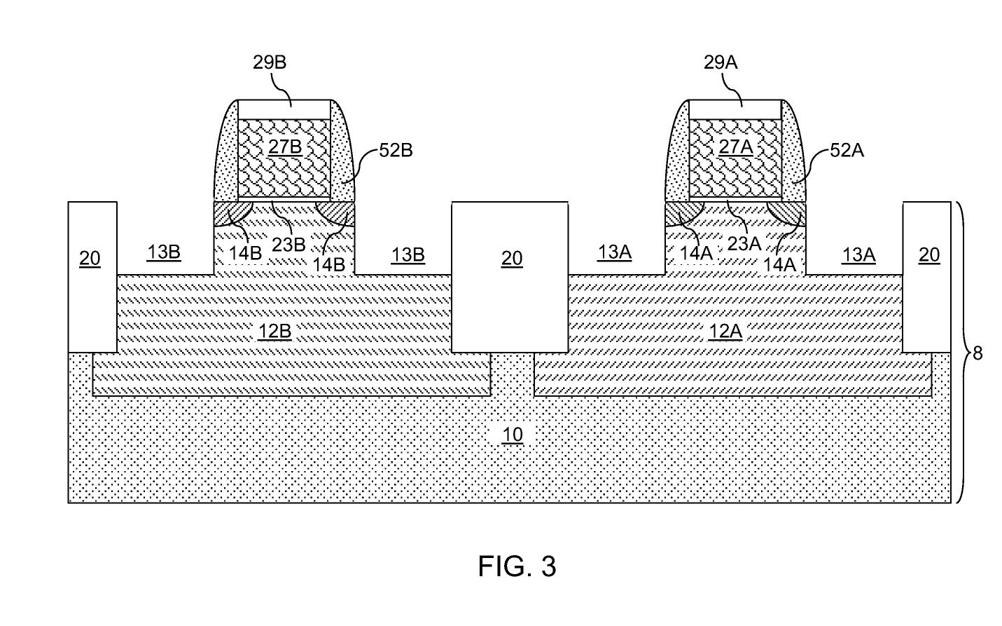

Referring to FIG. 3, gate spacers are formed on sidewalls of each of the disposable gate structures, for example, by deposition of a conformal dielectric material layer and an anisotropic etch. The gate spacers can include a first gate spacer 52A formed around the first disposable gate structure (23A, 27A, 29A) and a second gate spacer 52B formed around the second disposable gate structure (23B, 27B, 29B).

In one embodiment, semiconductor material can be removed from the portions of the semiconductor substrate that are not covered by the disposable gate structures, gate spacers (52A, 52B), or the shallow trench isolation structures 20 to form cavities within the semiconductor substrate 8. For example, first source/drain cavities 13A can be formed in the first device region, and second source/drain cavities 13B can be formed in the second device region by an anisotropic etch that removes the semiconductor materials of the second conductivity type well 12A and the first conductivity type well 12B. The depth of the first and second source/drain cavities (13A, 13B) does not exceed the depths of the second conductivity type well 12A and the first conductivity type well 12B, and preferably, does not exceed the depths of the shallow trench isolation structures 20. The first and second source/drain cavities (13A, 13B) can have substantially vertical sidewalls that are vertically coincident with a bottom portion of the outer sidewalls of the gate spacers (52A, 52B).

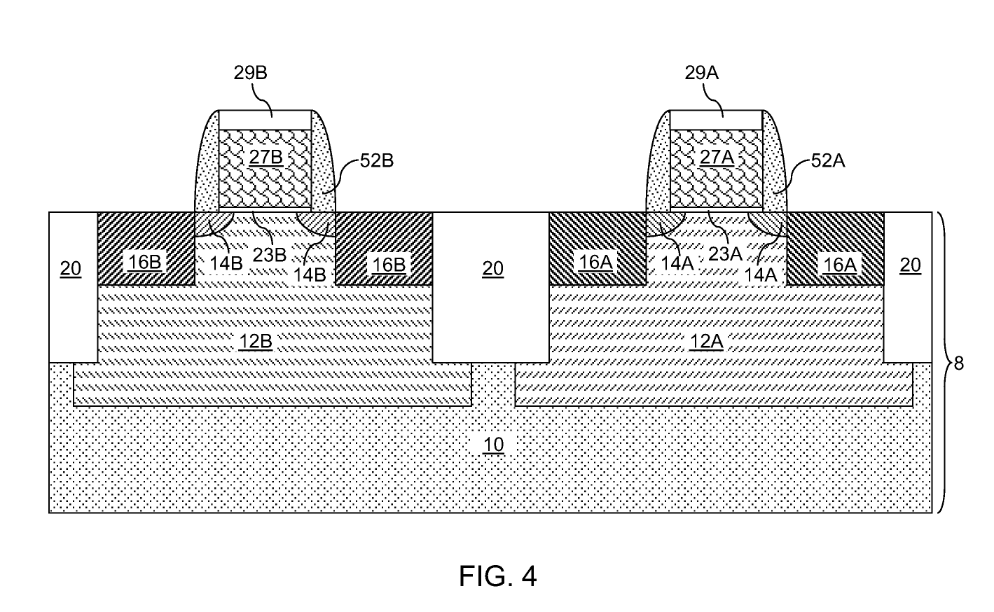

Referring to FIG. 4, a first dielectric liner (not shown) can be deposited and lithographically patterned to cover the second device region, while exposing the semiconductor surfaces on the first source/drain cavities 13A. First embedded stress-generating source/drain regions 16A are formed by selective epitaxy of a semiconductor material that is lattice mismatched relative to the semiconductor material of the second conductivity type well 12A.

For example, if the second conductivity type well 12A includes a p-doped single crystalline silicon and an n-type field effect transistor is to be formed in the second device region, the first embedded stress-generating source/drain regions 16A can include an n-doped single crystalline silicon-carbon alloy material in which the carbon concentration is between 0% and 2.5% in atomic concentration, which is the solubility limit of carbon in silicon. In this case, the first embedded stress-generating source/drain regions 16A apply a longitudinal tensile stress in channel of the n-type field effect transistor along the direction connecting the two first embedded stress-generating source/drain regions 16A. The longitudinal tensile stress along the direction of the channel of the n-type field effect transistor increases the mobility of minority carriers (electrons) in the channel region, and therefore, increases the on-current of the n-type field effect transistor.

Alternately, if the second conductivity type well 12A includes an n-doped single crystalline silicon and a p-type field effect transistor is to be formed in the first device region, the first embedded stress-generating source/drain regions 16A can include a p-doped single crystalline silicon-germanium alloy material, in which the germanium concentration can be between 0% and 30% in atomic concentration. In this case, the first embedded stress-generating source/drain regions 16A apply a longitudinal compressive stress in channel of the p-type field effect transistor along the direction connecting the two first embedded stress-generating source/drain regions 16A. The longitudinal compressive stress along the direction of the channel of the p-type field effect transistor increases the mobility of minority carriers (holes) in the channel region, and therefore, increases the on-current of the p-type field effect transistor.

A second dielectric liner (not shown) can be deposited and lithographically patterned to cover the first device region, while exposing the semiconductor surfaces on the first source/drain cavities 13A. Any remaining portion of the first dielectric liner is removed from the sidewalls and bottom surfaces of the second source/drain cavities 13B so that semiconductor surfaces of the first conductivity type well 12B are exposed at the sidewalls and bottom surfaces of the second source/drain cavities 13B. Second embedded stress-generating source/drain regions 16B are formed by selective epitaxy of a semiconductor material that is lattice mismatched relative to the semiconductor material of the first conductivity type well 12A.

The material of the second embedded stress-generating source/drain regions 16B can provide the opposite type of stress to the type of stress that the first embedded stress-generating source/drain regions 16A generate. Thus, if the first embedded stress-generating source/drain regions 16A generate a longitudinal tensile stress, the second embedded stress-generating source/drain regions 16B generate a longitudinal compressive stress. For example, the first conductivity type well 12B can include an n-doped single crystalline silicon, and the second embedded stress-generating source/drain regions 16B can include a p-doped single crystalline silicon-germanium alloy material, in which the germanium concentration can be between 0% and 30% in atomic concentration.

Alternately, if the first embedded stress-generating source/drain regions 16A generate a longitudinal compressive stress, the second embedded stress-generating source/drain regions 16B generate a longitudinal tensile stress. For example, the first conductivity type well 12B can include a p-doped single crystalline silicon, and the second embedded stress-generating source/drain regions 16B can include an n-doped single crystalline silicon-carbon alloy material, in which the carbon concentration can be between 0% and 2.5% in atomic concentration.

The topmost surfaces of the first and second embedded stress-generating source/drain regions 16A can be raised above, coplanar with, or recessed below, the plane of the bottom surfaces of the first and second disposable gate dielectric portions (23A, 23B) depending on the amount of the epitaxial material selectively deposited in the first and second source/drain cavities (13A, 13B).

Each of the first embedded stress-generating source region (one of 16A's) and the first embedded stress-generating drain region (the other of 16A's) is epitaxially aligned to a single crystalline semiconductor material of the second conductivity type well 12A, which subsequently functions as a body of a first field effect transistor. Each of the second embedded stress-generating source region (one of 16B's) and the second embedded stress-generating drain region (the other of 16B's) is epitaxially aligned to a single crystalline semiconductor material of the first conductivity type well 12B, which subsequently functions as a body of a second field effect transistor.

While the present disclosure is illustrated with an embodiment in which embedded stress-generating source/drain regions (16A, 16B) are employed, embodiments in which one or more of the embedded stress-generating source/drain regions (16A, 16B) are replaced with (a) source/drain region(s) that are formed by ion implantation of dopants can also be practiced. In such embodiment, dopants of the first conductivity type are implanted into portions of the second conductivity type well 12A that are not covered by the first disposable gate structure (23A, 27A, 29A) and the first gate spacer 52A to form first source and drain regions having a doping of the first conductivity type. The first conductivity type well 12B can be masked by a photoresist (not shown) during the implantation of the first conductivity type dopants to prevent implantation of the first conductivity type dopants therein. Similarly, dopants of the second conductivity type are implanted into portions of the first conductivity type well 12B that are not covered by the second disposable gate structure (23B, 27B, 29B) and the second gate spacer 52B to form second source and drain regions having a doping of the second conductivity type. The second conductivity type well 12A can be masked by a photoresist (not shown) during the implantation of the second conductivity type dopants to prevent implantation of the second conductivity type dopants therein.

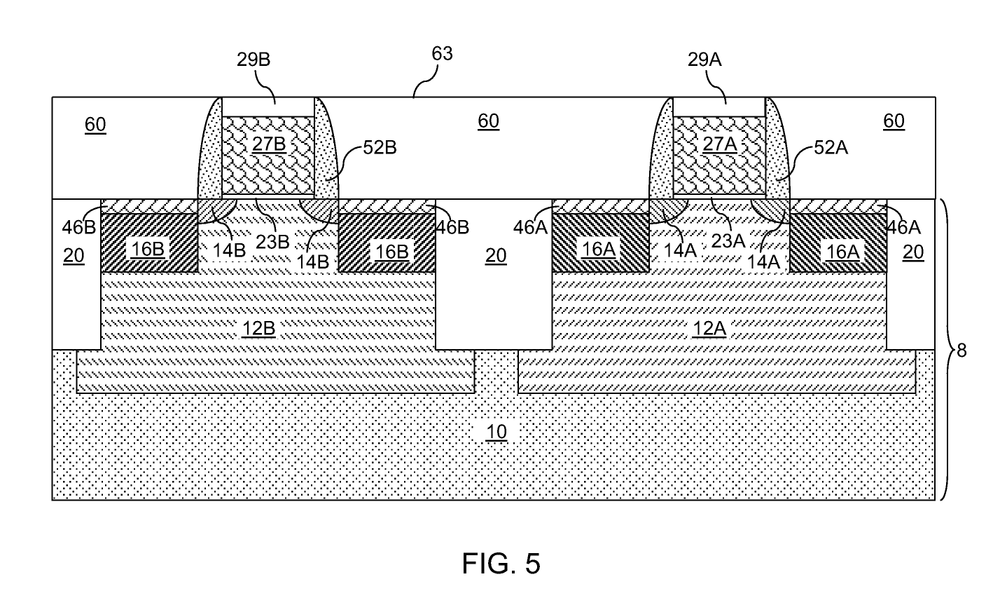

Referring to FIG. 5, first metal semiconductor alloy portions 46A and second metal semiconductor alloy portions 46B can be formed on exposed semiconductor material on the top surface of the semiconductor substrate 8, for example, by deposition of a metal layer (not shown) and an anneal. Unreacted portions of the metal layer are removed selective to reacted portions of the metal layer. The reacted portions of the metal layer constitute the metal semiconductor alloy portions (46A, 46B), which can include a metal silicide portions if the semiconductor material of the first and second embedded stress-generating source and drain regions (16A, 16B) include silicon.

The various metal semiconductor alloy portions (46A, 46B) include a first source-side metal semiconductor alloy portion (one of 46A's) formed on the first embedded stress-generating source region (one of 16A's), a first drain-side metal semiconductor alloy portion (the other of 16A's) formed on the first embedded stress-generating drain region (the other of 16A's), a second source-side metal semiconductor alloy portion (one of 46B's) formed on the second embedded stress-generating source region (one of 16B's), and a second drain-side metal semiconductor alloy portion (the other of 16B's) formed on the second embedded stress-generating drain region (the other of 16B's).

Optionally, a dielectric liner (not shown) may be deposited over the metal semiconductor alloy portions (46A, 46B), the first and second disposable gate structures (23A, 27A, 29A, 23B, 27B, 29B), and the first and second gate spacers (52A, 52B). Optionally, a first stress-generating liner (not shown) and a second stress-generating liner (not shown) can be formed over the first disposable gate structure (23A, 27A, 29A) and the second disposable gate structure (23B, 27B, 29B), respectively. The first stress-generating liner and the second stress-generating liner can include a dielectric material that generates a compressive stress or a tensile stress to underlying structures, and can be silicon nitride layers deposited by plasma enhanced chemical vapor deposition under various plasma conditions.

A planarization dielectric layer 60 can be deposited over the first stress-generating liner and/or the second stress-generating liner, if present, or over the metal semiconductor alloy portions (46A, 46B), the first and second disposable gate structures (23A, 27A, 29A, 23B, 27B, 29B), and the first and second gate spacers (52A, 52B) if (a) stress-generating liner(s) is/are not present. Preferably, the planarization dielectric layer 60 is a dielectric material that may be easily planarized. For example, the planarization dielectric layer 60 can be a doped silicate glass or an undoped silicate glass (silicon oxide).

The planarization dielectric layer 60 and any additional dielectric material layers (which include any of the first stress-generating liner, the second stress-generating liner, and the dielectric liner that are present, are planarized above the topmost surfaces of the first and second disposable gate structures (23A, 27A, 29A, 23B, 27B, 29B), i.e., above the topmost surfaces of the first and second disposable gate cap portions (29A, 29B). The planarization can be performed, for example, by chemical mechanical planarization (CMP). The planar topmost surface of the planarization dielectric layer 60 is herein referred to as a planar dielectric surface 63. The topmost surfaces of the disposable gate cap portions (29A, 29B) are coplanar with the planar dielectric surface 63 after the planarization.

The combination of the first source and drain extension regions 14A, the first embedded stress-generating source and drain regions 16A, and the second conductivity type well 12A can be employed to subsequently form a first field effect transistor. The combination of the second source and drain extension regions 14B, the second embedded stress-generating source and drain regions 16B, and the first conductivity type well 12B can be employed to subsequently form a second field effect transistor.

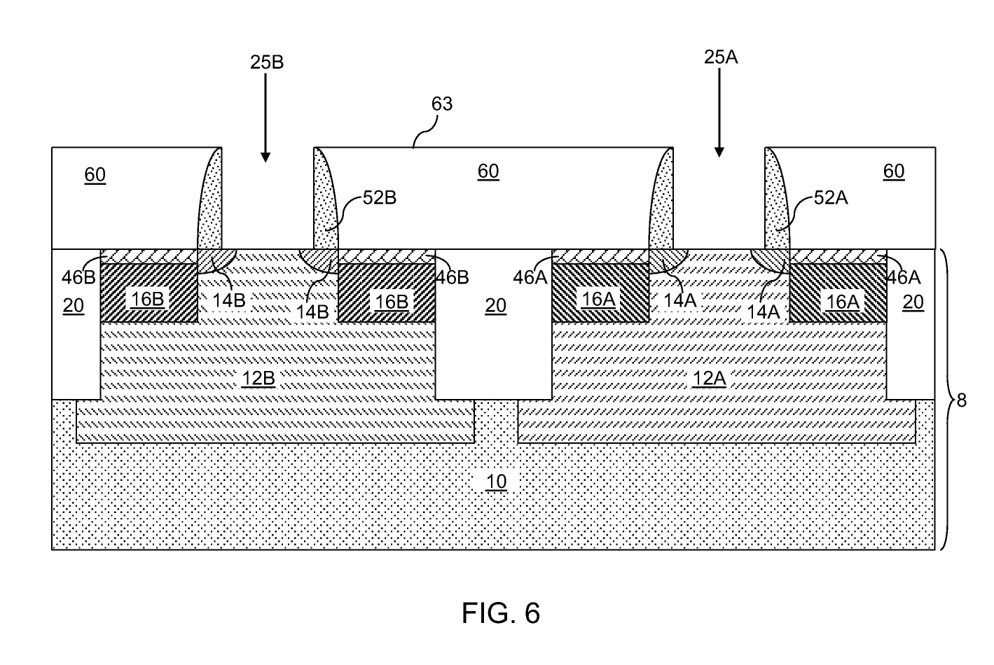

Referring to FIG. 6, the first disposable gate structure (23A, 27A, 29A) and the second disposable gate structure (23B, 27B, 29B) are removed by at least one etch. The first and second disposable gate structures (23A, 27A, 29A, 23B, 27B, 29B) can be removed, for example, by at least one etch, which can include an anisotropic etch, an isotropic etch, or a combination thereof. The at least one etch can include a dry etch and/or a wet etch. The at least one etch employed to remove the first and second disposable gate structures (23A, 27A, 29A, 23B, 27B, 29B) is preferably selective to the dielectric materials of the planarization dielectric layer 60 and any other dielectric material layer that is present above the semiconductor substrate 8.

A first gate cavity 25A is formed in the volume from which the first disposable gate structure (23A, 27A, 29A) is removed, and a second gate cavity 25B is formed in the volume from which the second disposable gate structure (23B, 27B, 29B) is removed. A semiconductor surface of the semiconductor substrate 8, i.e., the top surface of the second conductivity type well 12A, is exposed at the bottom of the first gate cavity 25A. Another semiconductor surface of the semiconductor substrate 8, i.e., the top surface of the first conductivity type well 12B, is exposed at the bottom of the second gate cavity 25B. Each of the first and second gate cavities (25A, 25B) is laterally surrounded by the planarization dielectric layer 60. The first gate spacer 52A laterally surrounds the first gate cavity 25A, and the second gate spacer 52B laterally surrounds the second gate cavity 25B. The inner sidewalls of the first gate spacer 52A can be substantially vertical, and extends from the top surface of the second conductivity type well 12A to the planar dielectric surface 63, i.e., the topmost surface, of the planarization dielectric layer 60. Further, the inner sidewalls of the second gate spacer 52B can be substantially vertical, and extends from the top surface of the first conductivity type well 12B to the planar dielectric surface 63 of the planarization dielectric layer 60.

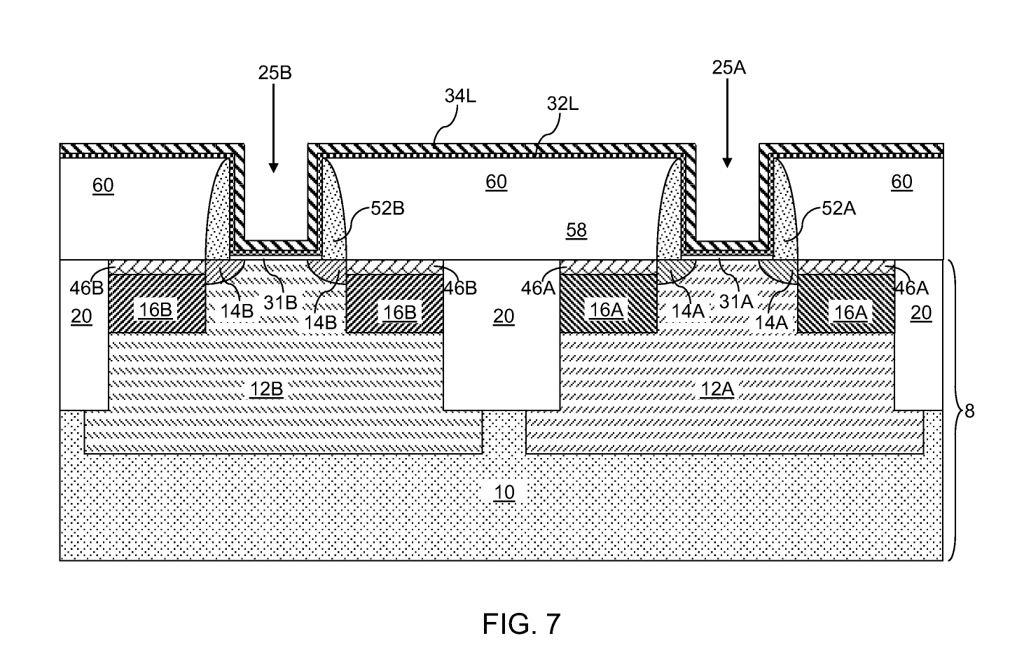

Referring to FIG. 7, exposed portions of the semiconductor surfaces of the semiconductor substrate 8 can be converted to a dielectric material layer. For example, a first semiconductor-element-containing dielectric layer 31A can be formed on the exposed surface of the second conductivity type well 12A by conversion of the exposed semiconductor material into a dielectric material, and a second semiconductor-element-containing dielectric layer 31B can be formed on the exposed surface of the first conductivity type well 12B by conversion of the exposed semiconductor material into the dielectric material. The formation of the semiconductor-element-containing dielectric layers (31A, 31B) can be effected by thermal conversion or plasma treatment. If the semiconductor material of the second conductivity type well 12A and the first conductivity type well 12B includes silicon, the semiconductor-element-containing dielectric layers (31A, 31B) can include silicon oxide or silicon nitride. The semiconductor-element-containing dielectric layers (31A, 31B) are interfacial dielectric layers that contact a semiconductor surface underneath and gate dielectrics to be subsequently deposited thereupon. The thickness of the semiconductor-element-containing dielectric layers (31A, 31B) can be from 0.3 nm to 1.2 nm, although lesser and greater thicknesses can also be employed.

A gate dielectric layer 32L is deposited on the bottom surfaces and sidewalls of the gate cavities (25A, 25B) and the topmost surface of the planarization dielectric layer 60. The gate dielectric layer 32L can be a high dielectric constant (high-k) material layer having a dielectric constant greater than 8.0. The gate dielectric layer 32L can include a dielectric metal oxide, which is a high-k material containing a metal and oxygen, and is known in the art as high-k gate dielectric materials. Dielectric metal oxides can be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the gate dielectric layer 32L, as measured at horizontal portions, can be from 0.9 nm to 6 nm, and preferably from 1.0 nm to 3 nm. The gate dielectric layer 32L may have an effective oxide thickness on the order of or less than 1 nm. In one embodiment, the gate dielectric layer 32L is a hafnium oxide (HfO₂) layer.

A first work function material layer 34L including a first metallic material having a first work function is deposited. The first work function material layer 34L can be a p-type work function material layer or an n-type work function material layer. As used herein, a “p-type work function material” refers to a material having a work function that is between the valence band energy level of silicon and the mid band gap energy level of silicon, i.e., the energy level equally separated from the valence band energy level and the conduction band energy level of silicon. As used herein, an “n-type work function material” refers to a material having a work function that is between the conduction band energy level of silicon and the mid band gap energy level of silicon.

For example, if the second conductivity type well 12A includes a p-doped single crystalline semiconductor material and the second device region includes an n-type field effect transistor, the first metallic material can have a work function that is closer to the conduction band energy level of the semiconductor material than to the valence band energy level of the semiconductor material. If the second conductivity type well 12A includes p-doped single crystalline silicon and the second device region includes an n-type field effect transistor, the first metallic material can have a work function between the conduction band energy level of silicon and the mid-band gap energy level, i.e., the energy level at the middle between the valence band edge and the conduction band edge of silicon. In this case, the first metallic material can include Hf, Ti, Zr, Cd, La, Tl, Yb, Al, Ce, Eu, Li, Pb, Tb, Bi, In, Lu, Nb, Sm, V, Zr, Ga, Mg, Gd, Y, TiAl, TaN, a stack thereof, a conductive oxide thereof, a conductive nitride thereof, an alloy thereof, and a combination thereof.

If the second conductivity type well 12A includes an n-doped single crystalline semiconductor material and the second device region includes a p-type field effect transistor, the first metallic material can have a work function that is closer to the valence band energy level of the semiconductor material than to the conduction band energy level of the semiconductor material. If the second conductivity type well 12A includes n-doped single crystalline silicon and the second device region includes a p-type field effect transistor, the first metallic material can have a work function between the valence band energy level of silicon and the mid-band gap energy level of silicon. In this case, the first metallic material can include Pt, Rh, Ir, Ru, Cu, Os, Be, Co, Pd, Te, Cr, Ni, TiN, a stack thereof, a conductive oxide thereof, a conductive nitride thereof, an alloy thereof, and a combination thereof.

The first work function material layer 34L can be deposited, for example, by physical vapor deposition (PVD) or chemical vapor deposition (CVD). The first work function material layer 34L may, or may not, be conformal. In other words, the vertical portions of the first work function material layer 34L may, or may not, have the same thickness as the horizontal portions of the first work function material layer 34L. The thickness of the horizontal portions of the first work function material layer 34L at the bottom of the first and second gate cavities (25A, 25B) can be from 2.5 nm to 10 nm, although lesser and greater thicknesses can also be employed.

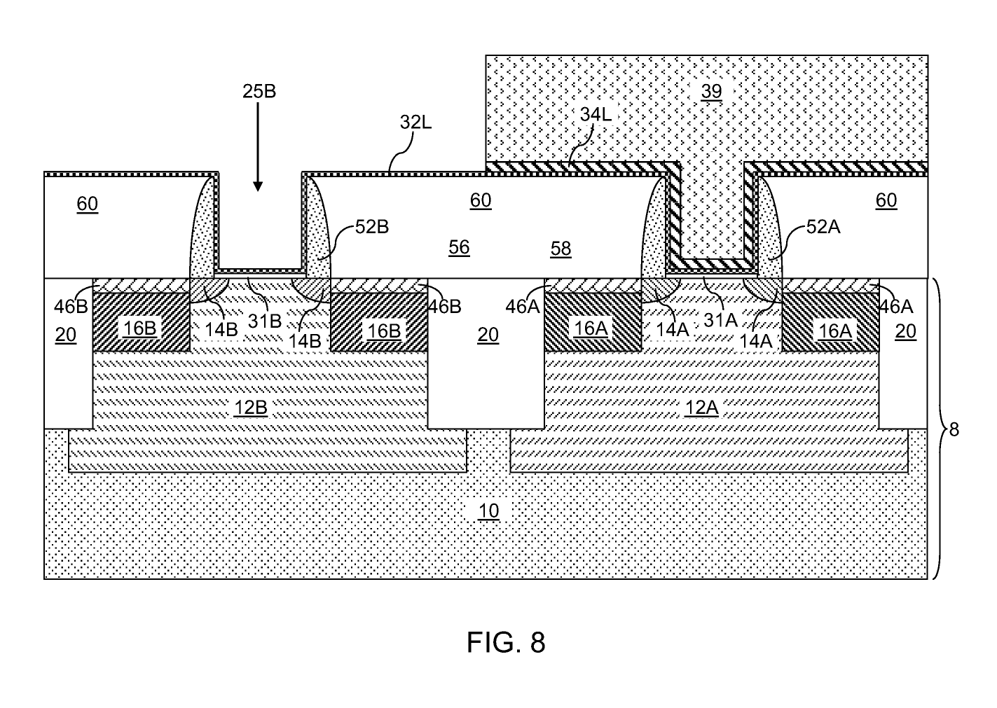

Referring to FIG. 8, a photoresist 39 is applied and lithographic patterned so that the photoresist 39 covers the area over the second conductivity type well 12A, while the first work function material layer 34L is are exposed over the first conductivity type well 12B. The exposed portion of the first work function material layer 34L is removed by an etch, which can be a wet etch or a dry etch. The photoresist 39 is removed, for example, by ashing or wet etching.

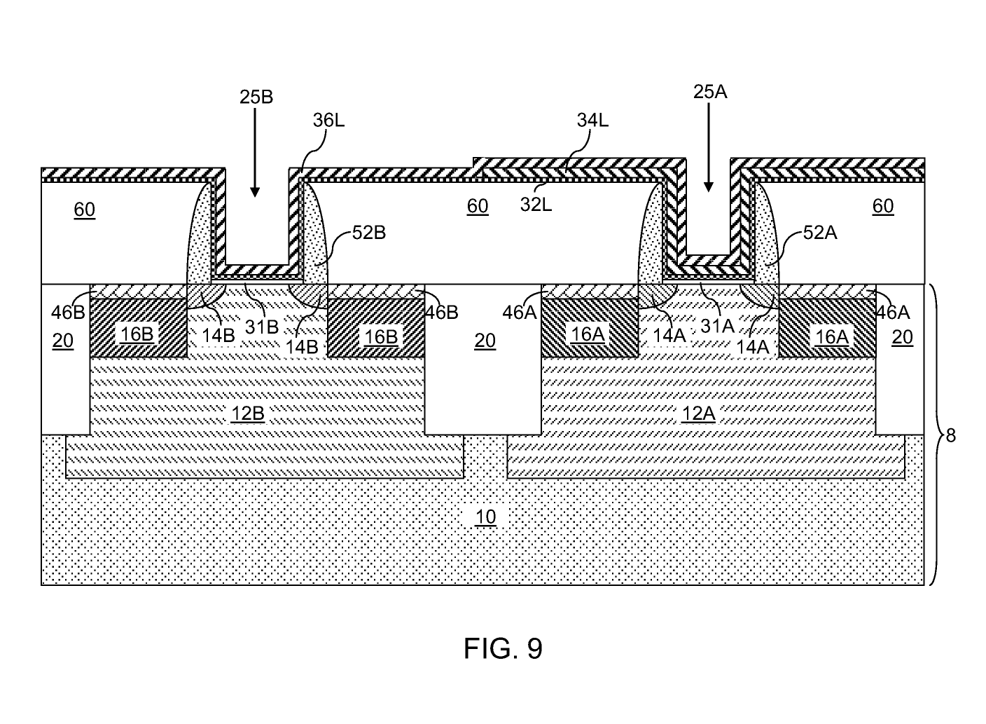

Referring to FIG. 9, a second work function material layer 36L including a second metallic material having a second work function is deposited. If the first work function material layer 34L is a p-type work function material layer, the second work function material layer 36L can be an n-type work function material layer, and vice versa.

For example, if the first conductivity type well 12B includes an n-doped single crystalline semiconductor material and the first device region includes a p-type field effect transistor, the second metallic material can have a work function that is closer to the valence band energy level of the semiconductor material than to the conduction band energy level of the semiconductor material. If the first conductivity type well 12B includes n-doped single crystalline silicon and the first device region includes a p-type field effect transistor, the second metallic material can have a work function between the valence band energy level of silicon and the mid-band gap energy level of silicon. In this case, the second metallic material can include Pt, Rh, Ir, Ru, Cu, Os, Be, Co, Pd, Te, Cr, Ni, TiN, a stack thereof, a conductive oxide thereof, a conductive nitride thereof, an alloy thereof, and a combination thereof.

If the first conductivity type well 12B includes a p-doped single crystalline semiconductor material and the second device region includes an n-type field effect transistor, the second metallic material can have a work function that is closer to the conduction band energy level of the semiconductor material than to the valence band energy level of the semiconductor material. If the first conductivity type well 12B includes p-doped single crystalline silicon and the second device region includes an n-type field effect transistor, the second metallic material can have a work function between the conduction band energy level of silicon and the mid-band gap energy level of silicon. In this case, the second metallic material can include Hf, Ti, Zr, Cd, La, Tl, Yb, Al, Ce, Eu, Li, Pb, Tb, Bi, In, Lu, Nb, Sm, V, Zr, Ga, Mg, Gd, Y, TiAl, TaN, a stack thereof, a conductive oxide thereof, a conductive nitride thereof, an alloy thereof, and a combination thereof.

The second work function material layer 36L can be deposited, for example, by physical vapor deposition (PVD) or chemical vapor deposition (CVD). The second work function material layer 36L may, or may not, be conformal. Thus, the vertical portions of the second work function material layer 36L may, or may not, have the same thickness as the horizontal portions of the second work function material layer 36L. The thickness of the horizontal portions of the first work function material layer 36L at the bottom of the first and second gate cavities (25A, 25B) can be from 2.5 nm to 10 nm, although lesser and greater thicknesses can also be employed.

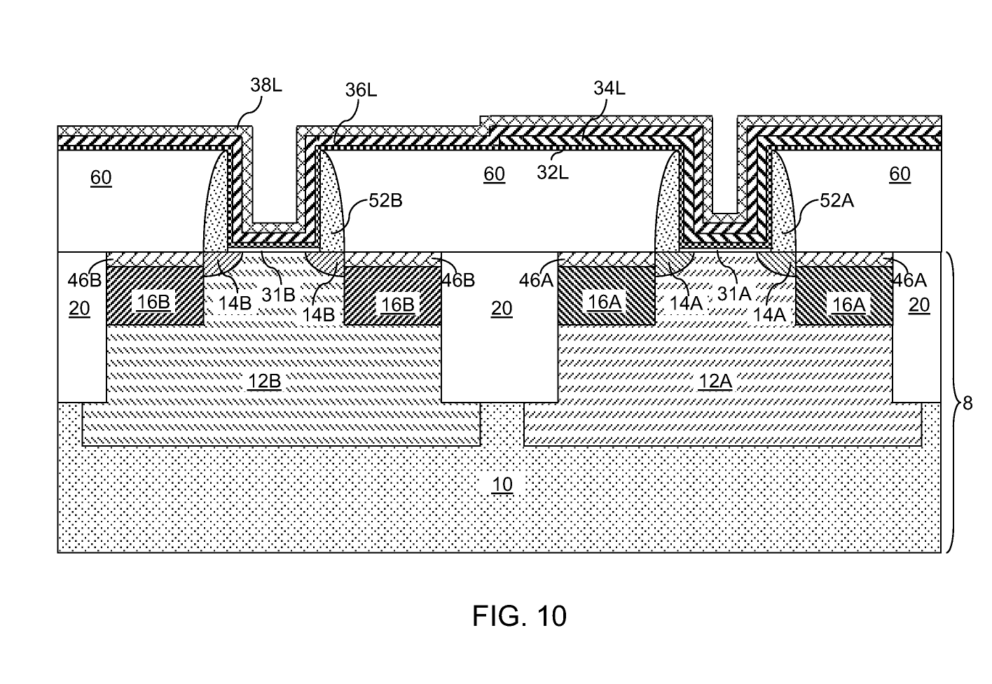

Referring to FIG. 10, a tungsten barrier layer 38L is deposited on the exposed surfaces of the second work function material layer 36L. The tungsten barrier layer 38L consists essentially of tungsten. The tungsten barrier layer 38L functions as a conductive diffusion barrier layer that blocks and prevents diffusion of metallic materials across the tungsten barrier layer 38L. Thus, the metallic materials of the first work function material layer 34L and the second work function material layer 36L do not diffuse through the tungsten barrier layer 38L to metal portions to be subsequently formed in the first and second gate cavities (25A, 25B), and the metallic materials of the metal portions do not diffuse through the tungsten barrier layer 38L to the first work function material layer 34L or the second work function material layer 36L. Further, due to the high melting point of tungsten, the functionality of the tungsten barrier layer 38L as a diffusion barrier layer for metallic materials is not significantly affected during thermal cycling of the exemplary semiconductor structure during subsequent processing steps.

The tungsten barrier layer 38L can be deposited, for example, by physical vapor deposition (PVD), chemical vapor deposition (CVD), or a combination thereof. The contour of the tungsten barrier layer 38L follows the contour of the second work function material layer 36, which is a single contiguous layer without a hole therein. Thus, the tungsten barrier layer 38L is also formed as a single contiguous layer without any hole therein. Depending on the deposition method employed, the tungsten barrier layer 38L may, or may not, be conformal. In other words, the vertical portions of the tungsten barrier layer 38L may, or may not, have the same thickness as the horizontal portions of the tungsten barrier layer 38L. The thickness of the tungsten barrier layer 38L, as measured at the bottom portion of the first gate cavity 25A or at the bottom of the second gate cavity 25B, can be from 0.5 nm to 20 nm, although lesser and greater thicknesses can also be employed.

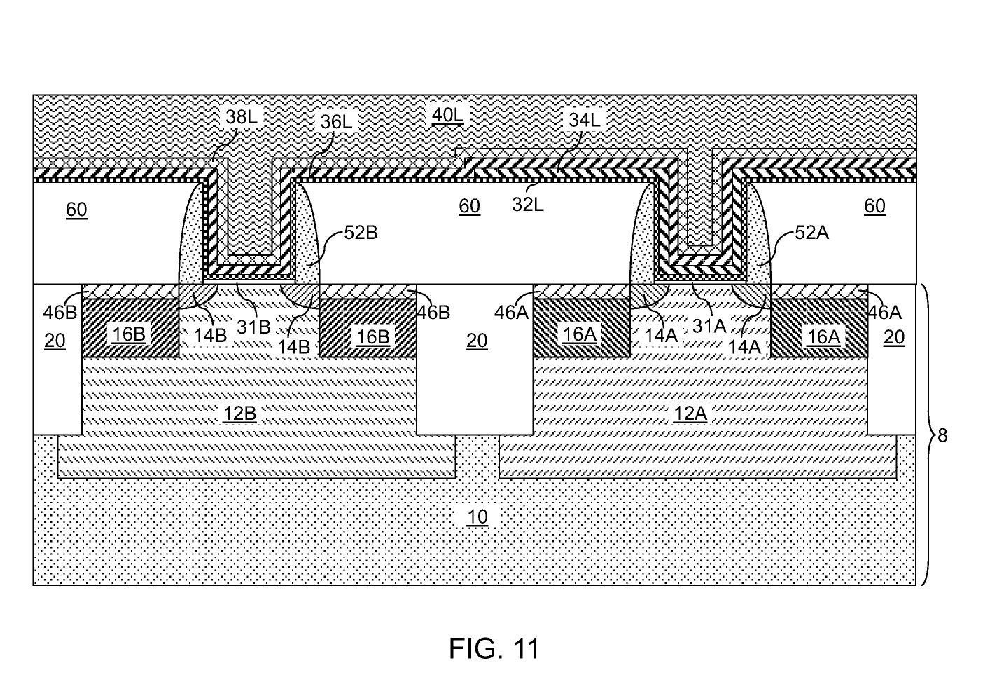

Referring to FIG. 11, the gate cavities (25A, 25B) are filled with a metal layer 40L. The metal layer 40L is deposited directly on the tungsten barrier layer 38L. The metal layer 40L includes a metal, which can be deposited by physical vapor deposition or chemical vapor deposition. For example, the metal layer 40L can be an aluminum layer or an aluminum alloy layer deposited by physical vapor deposition. The thickness of the metal layer 40L, as measured in a planar region of the metal layer 40L above the top surface of the planarization dielectric layer 60, can be from 100 nm to 500 nm, although lesser and greater thicknesses can also be employed. In one embodiment, the metal layer 40L can include at least one material selected from Al, Au, Ag, and Cu. Further, the metal layer 40L can consist essentially of a single elemental metal such as Al, Au, Ag, or Cu. For example, the metal layer 40L can consist essentially of aluminum.

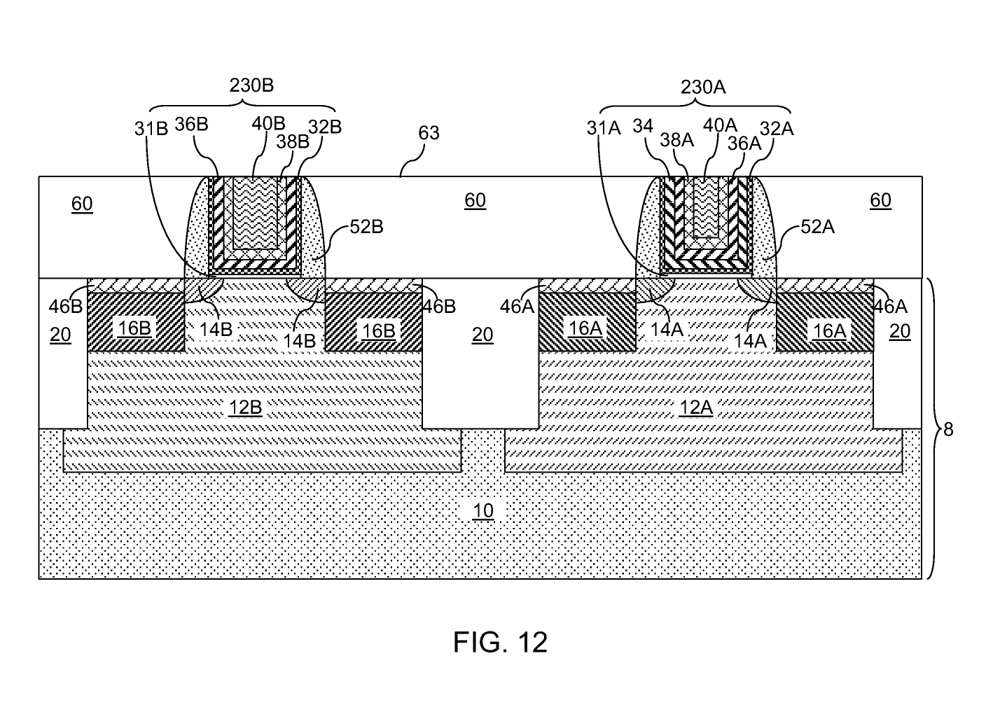

Referring to FIG. 12, the metal layer 40L, the tungsten barrier layer 38L, the second work function material layer 36L, the first work function material layer 34L, and the gate dielectric layer 32L are planarized, for example, by chemical mechanical planarization. Specifically, portions of the metal layer 40L, the tungsten barrier layer 38L, the second work function material layer 36L, the first work function material layer 34L, and the gate dielectric layer 32L are removed from above the planar dielectric surface 63 of the planarization dielectric layer 60 at the end of the planarization step. The remaining portion of the gate dielectric layer 32L in the first device region forms a first gate dielectric 32A, and the remaining portion of the gate dielectric layer 32L in the second device region forms a second gate dielectric 32B. The remaining portion of the first work function material layer 34L in the first device region forms a first work function material portion 34. The remaining portion of the second work function material layer 36L in the first device region forms a second work function material portion 36A. The remaining portion of the second work function material layer 36L in the second device region forms a work function material portion 36B. The remaining portion of the tungsten barrier layer 38L in the first device region forms a first tungsten barrier portion 38A, and the remaining portion of the barrier layer in the second device region forms a second tungsten barrier portion 38B. The remaining portion of the metal layer 40L in the first device region constitutes a first metal portion 40A, and the remaining portion of the metal layer in the second device region constitutes a second metal portion 40B. The topmost surfaces of the first and second gate dielectrics (32A, 32B), the first and second work function material portions (34, 36A), the work function material portion 36B, the first and second tungsten barrier portions (38A, 38B), and the first and second metal portions (40A, 40B) are coplanar with the topmost surface of the planarization dielectric layer 60.

Thus, replacement gate stacks are formed within the volume previously occupied by the first and second gate cavities (25A, 25B) at the step of FIG. 6. The replacement gate stacks include a first replacement gate stack 230A located in the first device region and a second replacement gate stack 230B located in the second device region. Each replacement gate stack (230A, 230B) overlies a channel region of a field effect transistor. The first replacement gate stack 230A and the second replacement gate stack 230B are formed concurrently.

A first field effect transistor is formed in the first device region. The first field effect transistor includes the second conductivity type well 12A, the first source/drain extension regions 14A, the first embedded stress-generating source/drain regions 16A, the first metal semiconductor alloy portions 46A, the first replacement gate stack 230A, and the first gate spacer 52A. The first replacement gate stack 230A includes the first semiconductor-element-containing dielectric layer 31A, the first gate dielectric 32A, the first planar work function material portion 34, the second planar work function material portion 36A, the first tungsten barrier portion 38A, and the first metal portion 40A.

A second field effect transistor is formed in the second device region. The second field effect transistor includes the first conductivity type well 12B, the second source/drain extension regions 14B, the second embedded stress-generating source/drain regions 16B, second metal semiconductor alloy portions 46B, the second replacement gate stack 230B, and the second gate spacer 52B. The second replacement gate stack 230B includes the second semiconductor-element-containing dielectric layer 31B, the second gate dielectric 32B, the work function material portion 36B, the second tungsten barrier portion 38B, and the second metal portion 40B. The second planar work function material portion 36A in the first replacement gate stack 230A and the work function material portion 36B in the second replacement gate stack 230B have the same material composition and the same thickness.

Each of the first and second gate dielectrics (32A, 32B) is a U-shaped gate dielectric, which includes a horizontal gate dielectric portion and a vertical gate dielectric portion extending upward from peripheral regions of the horizontal gate dielectric portion. In the first field effect transistor, the first work function material portion 34 contacts inner sidewalls of the vertical gate dielectric portion of the first gate dielectric 32A. In the second field effect transistor, the work function material portion 36B contacts inner sidewalls of the vertical gate dielectric portion of the second gate dielectric 32B. Each U-shaped gate dielectric is located on the semiconductor substrate 8 and is embedded in the planarization dielectric layer 60.

Each gate dielectric (32A, 32B), as a U-shaped gate dielectric, includes a horizontal gate dielectric portion and a vertical gate dielectric portion. The vertical gate dielectric portion contiguously extends from the horizontal gate dielectric portion to the topmost surface of the planarization dielectric layer 60.

Each of the first work function material portion 34, the second work function material portion 36A, and the work function material portion 36B can include a p-type work function material portion or an n-type work function material portion. Thus, each of the first work function material portion 34, the second work function material portion 36A, and the work function material portion 36B can include a metallic material selected from Pt, Rh, Ir, Ru, Cu, Os, Be, Co, Pd, Te, Cr, Ni, TiN, Hf, Ti, Zr, Cd, La, Tl, Yb, Al, Ce, Eu, Li, Pb, Tb, Bi, In, Lu, Nb, Sm, V, Zr, Ga, Mg, Gd, Y, TiAl, TaN, a stack thereof, a conductive oxide thereof, a conductive nitride thereof, an alloy thereof, and a combination thereof.

The stack of the first work function material portion 34 and the second work function material portion 36A can include a stack, from bottom to top or from top to bottom, of a p-type work function material portion and an n-type work function material portion. Thus, within the stack of the first work function material portion 34 and the second work function material portion 36A, the first work function material portion 34 includes a first metallic material and the second work function material portion 36A includes a second material. In one embodiment, the first material can be selected from Pt, Rh, Ir, Ru, Cu, Os, Be, Co, Pd, Te, Cr, Ni, TiN, a stack thereof, a conductive oxide thereof, a conductive nitride thereof, an alloy thereof, and a combination thereof, and the second metallic material can be selected from Hf, Ti, Zr, Cd, La, Tl, Yb, Al, Ce, Eu, Li, Pb, Tb, Bi, In, Lu, Nb, Sm, V, Zr, Ga, Mg, Gd, Y, TiAl, TaN, a stack thereof, a conductive oxide thereof, a conductive nitride thereof, an alloy thereof, and a combination thereof. In another embodiment, the first material can be selected from Hf, Ti, Zr, Cd, La, Tl, Yb, Al, Ce, Eu, Li, Pb, Tb, Bi, In, Lu, Nb, Sm, V, Zr, Ga, Mg, Gd, Y, TiAl, TaN, a stack thereof, a conductive oxide thereof, a conductive nitride thereof, an alloy thereof, and a combination thereof, and the second metallic material can be selected from Pt, Rh, Ir, Ru, Cu, Os, Be, Co, Pd, Te, Cr, Ni, TiN, a stack thereof, a conductive oxide thereof, a conductive nitride thereof, an alloy thereof, and a combination thereof.

The entirety of inner sidewalls of the second work function material portion 36B contacts the entirety of outer sidewalls of the first tungsten barrier portion 38A, and the entirety of inner sidewalls of the work function material portion 36B contacts the entirety of outer sidewalls of the second tungsten barrier portion 38B. The second work function material portion 36A laterally surrounds and embeds the first tungsten barrier portion 38A. The work function material portion 36B laterally surrounds and embeds the second tungsten barrier portion 38B.

Each of the first tungsten barrier portion 38A and the second tungsten barrier portion 38B is formed as a U-shaped tungsten barrier portion that includes a horizontal tungsten portion and a vertical tungsten portion. The vertical tungsten portion contiguously extends from the horizontal tungsten portion to the topmost surface of the planarization dielectric layer 60. The entirety of inner sidewalls of the first tungsten barrier portion 38A contacts the entirety of sidewalls of the first metal portion 40A, and the entirety of inner sidewalls of the second tungsten barrier portion 38B contacts the entirety of sidewalls of the second metal portion 40B. The first tungsten barrier portion 38A laterally surrounds and embeds the first metal portion 40A. The second tungsten barrier portion 38B laterally surrounds and embeds the second metal portion 40B.

Each of the first and second metal portions (40A, 40B) includes at least one metal, which can be selected from Al, Au, Cg, and Cu. In one embodiment, each of the first and second metal portions (40A, 40B) can consist essentially of a single elemental metal, which can be selected from Al, Au, Cg, and Cu. In one embodiment, each of the first and second metal portions (40A, 40B) can include a metal consisting essentially of Al.

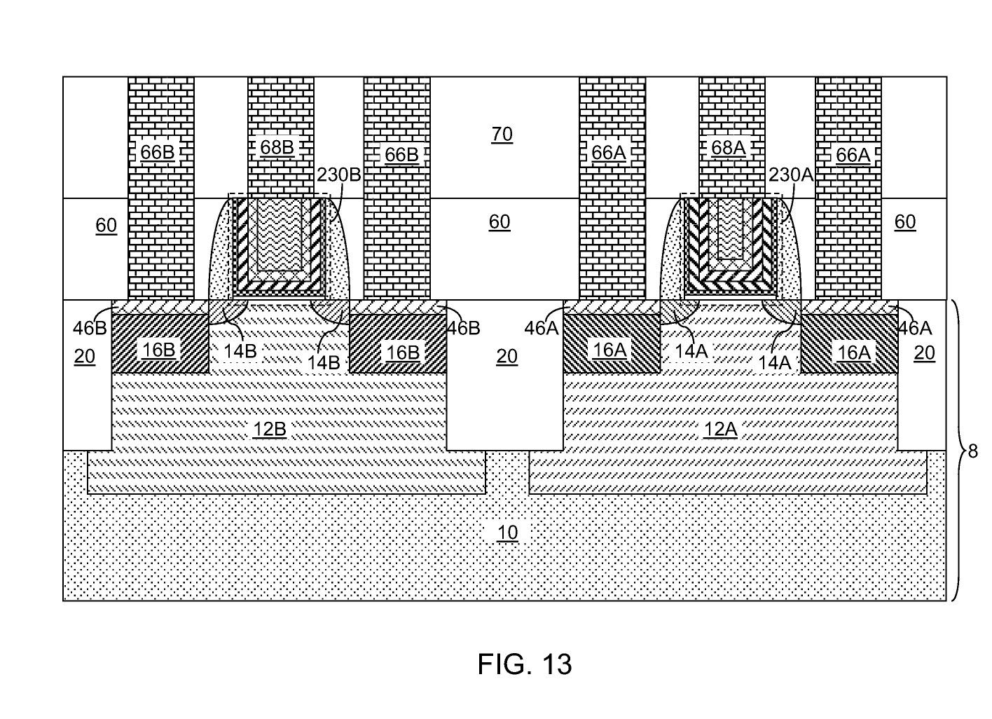

Referring to FIG. 13, a contact level dielectric layer 70 is deposited over the planarization dielectric layer 60. Various contact via structures can be formed, for example, by formation of contact via cavities by a combination of lithographic patterning and an anisotropic etch followed by deposition of a metal and planarization that removes an excess portion of the metal from above the contact level dielectric layer 70. The various contact via structures can include, for example, first source/drain contact via structures (i.e., at least one first source contact via structure and at least one first drain contact via structure) 66A, second source/drain contact via structures (i.e., at least one second source contact via structure and at least one second drain contact via structure) 66B, a first gate contact via structure 68A, and a second gate contact via structure 68B. Each source contact via structure (66A, 66B) and each drain contact via structure (66A, 66B) are embedded in the planarization dielectric layer 60 and the contact level dielectric material layer 70. Each source contact via structure (one of 66A and 66B) contacts a source-side metal semiconductor alloy portion (one of 46A and 46B), and each drain contact via structure (another of 66A and 66B) contacts a drain-side metal semiconductor alloy portion (another of 46A and 46B).

While the disclosure has been described in terms of specific embodiments, it is evident in view of the foregoing description that numerous alternatives, modifications and variations will be apparent to those skilled in the art. Accordingly, the disclosure is intended to encompass all such alternatives, modifications and variations which fall within the scope and spirit of the disclosure and the following claims.

What is claimed is:

1. A semiconductor structure comprising a field effect transistor (FET) including a gate stack, said gate stack comprising:
a gate dielectric located on a semiconductor substrate;
at least one work function material portion contacting said gate dielectric;
a tungsten barrier portion contacting said at least one work function material portion; and
a metal portion contacting said tungsten barrier portion.

2. The semiconductor structure of claim 1, wherein said tungsten barrier portion is a U-shaped tungsten barrier portion including a horizontal tungsten portion and a vertical tungsten portion and embedding said metal portion therein.

3. The semiconductor structure of claim 2, wherein said metal portion includes a metal comprising at least one of Al, Cu, Ag, and Au.

4. The semiconductor structure of claim 3, wherein said metal portion includes a metal consisting essentially of Al.

5. The semiconductor structure of claim 1, wherein said gate dielectric is a U-shaped gate dielectric including a horizontal gate dielectric portion and a vertical gate dielectric portion, wherein said vertical gate dielectric portion contiguously extends from said horizontal gate dielectric portion to a topmost surface of a planarization dielectric layer.

6. The semiconductor structure of claim 5, wherein said FET further comprises a gate spacer having inner sidewalls that contact said vertical gate dielectric portion.

7. The semiconductor structure of claim 5, wherein each of said at least one work function material portion is a U-shaped work function material portion having a horizontal work function material portion and a vertical work function material portion, wherein said vertical work function material portion contiguously extends from said horizontal work function material portion to said topmost surface of said planarization dielectric layer.

8. The semiconductor structure of claim 1, wherein said at least one work function material portion is a plurality of work function material portions including a p-type work function material portion and an n-type work function material portion.

9. The semiconductor structure of claim 1, wherein topmost surfaces of said gate dielectric, said at one work function material portion, said tungsten barrier portion, and said metal portion are coplanar.

10. The semiconductor structure of claim 9, wherein said FET further comprises a planarization dielectric layer having a top surface that is coplanar with said topmost surfaces of said gate dielectric, said at one work function material portion, said tungsten barrier portion, and said metal portion.

11. The semiconductor structure of claim 10, wherein said FET further comprises:
an embedded stress-generating source region and an embedded stress-generating drain region that are epitaxially aligned to a single crystalline semiconductor material of a body of said FET;
a source-side metal semiconductor alloy portion and a drain-side metal semiconductor alloy portion located on said embedded stress-generating source region and said embedded stress-generating drain region, respectively;
a contact level dielectric material layer located above said planarization dielectric layer; and
a source contact via structure and a drain contact via structure embedded in said planarization dielectric layer and said contact level dielectric material layer and contacting said source-side metal semiconductor alloy portion and said drain-side metal semiconductor alloy portion, respectively.

12. A method of forming a semiconductor structure including a field effect transistor (FET), said method comprising:
forming a gate cavity laterally surrounded by a planarization dielectric layer on a semiconductor substrate, wherein a top surface of said semiconductor substrate is exposed at a bottom of said gate cavity;
forming a gate dielectric within the gate cavity;
forming at least one work function material portion on said gate dielectric;
forming a tungsten barrier portion on at least one work function material portion; and
forming a metal portion on said tungsten barrier portion, wherein said gate dielectric, said at least one work function material portion, said tungsten barrier portion, and said metal portion fill said gate cavity.

13. The method of claim 12, further comprising:
forming a disposable gate structure on said semiconductor substrate prior to forming said planarization dielectric layer;
planarizing said planarization dielectric layer, wherein a topmost surface of said disposable gate dielectric is coplanar with a top surface of said planarization dielectric layer after said planarizing, and said gate cavity is formed by removing said disposable gate structure.

14. The method of claim 12, wherein said tungsten barrier portion is formed as a U-shaped tungsten barrier portion including a horizontal tungsten portion and a vertical tungsten portion and embedding said metal portion therein.

15. The method of claim 14, wherein said metal portion includes a metal comprising Al, Cu, Ag, and Au.

16. The method of claim 15, wherein said metal portion includes a metal consisting essentially of Al.

17. The method of claim 12, wherein said gate dielectric is formed as a U-shaped gate dielectric including a horizontal gate dielectric portion and a vertical gate dielectric portion, wherein said vertical gate dielectric portion contiguously extends from said horizontal gate dielectric portion to a topmost surface of a planarization dielectric layer.

18. The method of claim 17, wherein each of said at least one work function material portion is formed as a U-shaped work function material portion having a horizontal work function material portion and a vertical work function material portion, wherein said vertical work function material portion contiguously extends from said horizontal work function material portion to said topmost surface of said planarization dielectric layer.

19. The method of claim 12, wherein said at least one work function material portion is formed as a plurality of work function material portions including a p-type work function material portion and an n-type work function material portion.

20. The method of claim 12, further comprising:
forming an embedded stress-generating source region and an embedded stress-generating drain region that are epitaxially aligned to a single crystalline semiconductor material of a body of said FET in said semiconductor substrate;
forming a source-side metal semiconductor alloy portion and a drain-side metal semiconductor alloy portion on said embedded stress-generating source region and said embedded stress-generating drain region, respectively;
forming a contact level dielectric material layer above said planarization dielectric layer; and
forming a source contact via structure and a drain contact via structure in said planarization dielectric layer and said contact level dielectric material layer and directly on said source-side metal semiconductor alloy portion and said drain-side metal semiconductor alloy portion, respectively.
